(19) United States
(12) Patent Application Publication
(10) Pub. No.: US 2026/0372137 A1
(43) Pub. Date: Nov. 19, 2026

(54) SEMICONDUCTOR PACKAGE INCLUDING LOOP WIRE STRUCTURE

(71) Applicant: Samsung Electronics Co., Ltd., Suwon-si (KR)

(72) Inventors: Daewoong Heo, Suwon-si (KR); Chihong Shin, Suwon-si (KR)

(21) Appl. No.: 19/668,533

(22) Filed: May 5, 2026

(30) Foreign Application Priority Data
May 14, 2025 (KR) 10-2025-0062827

(51) Int. Cl. H10W 70/65; H10W 20/41; H10W 72/50

(52) U.S. Cl. CPC H10W 70/65; H10W 20/425; H10W 72/533; H10W 72/536

(57) ABSTRACT

A semiconductor package includes a semiconductor device with a chip pad on an upper surface thereof, a conductive plate laterally spaced apart from the semiconductor device in a planar view, a first loop conductive wire provided on the conductive plate, and a second conductive wire connecting the chip pad to the first loop conductive wire, where each of a first end and a second end of the first loop conductive wire is connected to the conductive plate.

### CROSS-REFERENCE TO RELATED APPLICATION

This application is based on and claims priority under 35 U.S.C. § 119 to Korean Patent Application No. 10-2025-0062827, filed on May 14, 2025, in the Korean Intellectual Property Office, the disclosure of which is incorporated by reference herein in its entirety.

### BACKGROUND

With regard to semiconductor packages, a chip pad provided in one or more semiconductor devices may be electrically connected to an external conductive element through a bonding wire. In some examples, multiple semiconductor devices may be stacked.

### SUMMARY

In some examples, multiple semiconductor devices may be stacked or pitches between a plurality of chip pads of semiconductor devices may decrease, and thus it may be desired to reduce interference with a bonding wire and another bonding wire in semiconductor packages and improve the reliability of connection between a bonding wire and a conductive element.

The present disclosure provides a semiconductor package in which the reliability of connection of conductive wires is improved and interference between adjacent conductive wires is prevented.

The problems to be solved by the present disclosure are not limited to the above-mentioned problems, and other problems not mentioned will be clearly understood by one or ordinary skill in the art from the following description.

In some aspects, the present disclosure provides a semiconductor device with a chip pad on an upper surface thereof, a conductive plate spaced laterally apart from the semiconductor device in a planar view, a first loop conductive wire provided on the conductive plate, and a second conductive wire connecting the chip pad to the first loop conductive wire, where each of a first end and a second end of the first loop conductive wire is connected to the conductive plate.

In some aspects, the present disclosure provides a semiconductor package including a semiconductor device with a chip pad on an upper surface thereof, a conductive plate spaced laterally apart from the semiconductor device in a planar view, a first loop conductive wire provided on the conductive plate, and a second conductive wire connecting the chip pad to the first loop conductive wire, where each of a first end and a second end of the first loop conductive wire is connected to the same conductive plate, the second conductive wire includes a third end and a fourth end, the third end is connected to the chip pad, and the fourth end is directly connected to the first loop conductive wire, and a part of the first loop conductive wire protrudes from a position of the first end in a direction in which the semiconductor device is disposed so as to be closer to the semiconductor device than the first end.

In some aspects, the present disclosure provides a semiconductor package including a semiconductor device with a plurality of chip pads on one surface thereof, a plurality of conductive plates spaced apart from the semiconductor device, a plurality of first loop conductive wires respectively provided on at least some of the plurality of conductive plates, and a plurality of second conductive wires connecting at least some of the plurality of chip pads to the plurality of first loop conductive wires corresponding to at least some of the plurality of chip pads, where a first end and a second end of each of the plurality of first loop conductive wires are connected to each of the same plurality of conductive plates, the first end is a wire ball, and the second end is a stitch, a third end of each of the plurality of second conductive wires is connected to each of the plurality of chip pads, a fourth end of each of the plurality of second conductive wires is directly connected to each of the corresponding plurality of first loop conductive wires, the third end is a wire ball, and the fourth end is a stitch, the first end is disposed on the conductive plate to be closer to the semiconductor device than the second end, each of the plurality of first loop conductive wires includes a first vertical extension, a first horizontal extension, and a first inclined extension, the first vertical extension is connected to the first end, the first inclined extension is connected to the second end, and the first horizontal extension is connected to the first inclined extension, a first angle between the first vertical extension and a plane of each of the plurality of conductive plates is in a range of 80 ° to 100 °, a first inclination angle formed between the first inclined extension and each of the plurality of conductive plates is in a range of 10 ° to 40 °, and in a planar view, a second inclination angle formed between the first horizontal extension and each of the plurality of second conductive wires is in a range of 0 ° to 30 °.

### BRIEF DESCRIPTION OF THE DRAWINGS

FIG. 1 is a side view of an example of a semiconductor package.

FIG. 2A is an enlarged side view of a portion of an example of a semiconductor package.

FIG. 2B is an enlarged side view of a portion of an example of a semiconductor package.

FIG. 3 is a planar view of an example of a semiconductor package.

FIG. 4A is an enlarged side view of a portion of an example of a semiconductor package.

FIG. 4B is an enlarged side view of a portion of an example of a semiconductor package.

FIG. 5A is an enlarged side view of a portion of an example of a semiconductor package.

FIG. 5B is an enlarged side view of a portion of an example of a semiconductor package.

FIG. 5C is an enlarged side view of a portion of an example of a semiconductor package.

FIG. 6 is an enlarged side view of a portion of an example of a semiconductor package.

FIG. 7A is an enlarged side view of a portion of an example of a semiconductor package.

FIG. 7B is an enlarged side view of a portion of an example of a semiconductor package.

FIG. 7C is a planar view of an example of a semiconductor package.

FIGS. 8A-8F are side views sequentially illustrating an example method of manufacturing a semiconductor package.

FIGS. 9A-9C are side views sequentially illustrating an example method of manufacturing a semiconductor package.

### DETAILED DESCRIPTION

Hereinafter, implementations of the present disclosure will be described in detail with reference to the accompanying drawings.

Implementations are provided to more completely explain the aspects of present disclosure to one of ordinary skill in the art, and the following implementations may be modified in various different forms. In addition, the thickness or size of each layer in the drawings may be exaggerated for convenience and clarity of explanation.

Herein, a first direction may refer to an X direction, a second direction may refer to a Y direction, and the first direction and the second direction may be perpendicular to each other. A third direction may be a Z direction, and perpendicular to each of the first direction and the second direction. A horizontal plane or plane refers to an X-Y plane. An upper surface of a specific object means one surface located in a positive third direction with respect to the specific object, and a lower surface of the specific object means one surface located in a negative third direction with respect to the specific object.

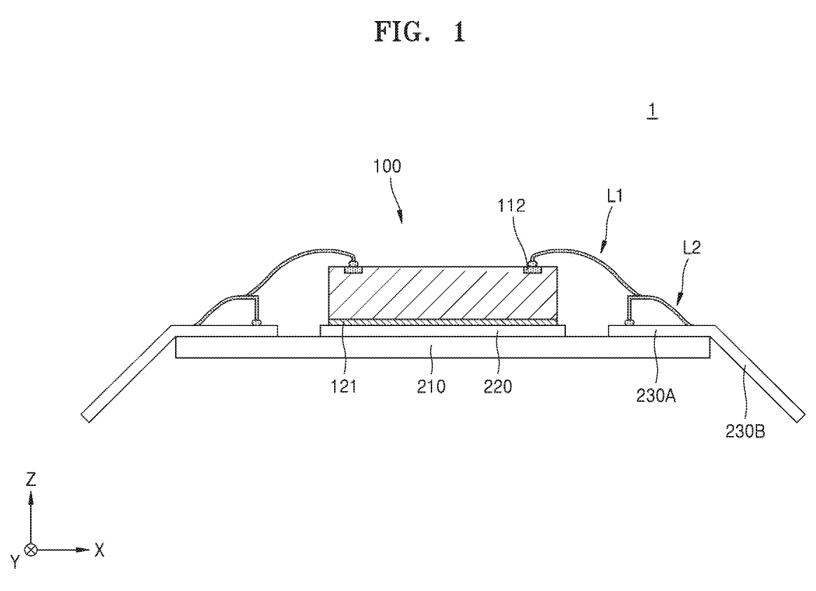

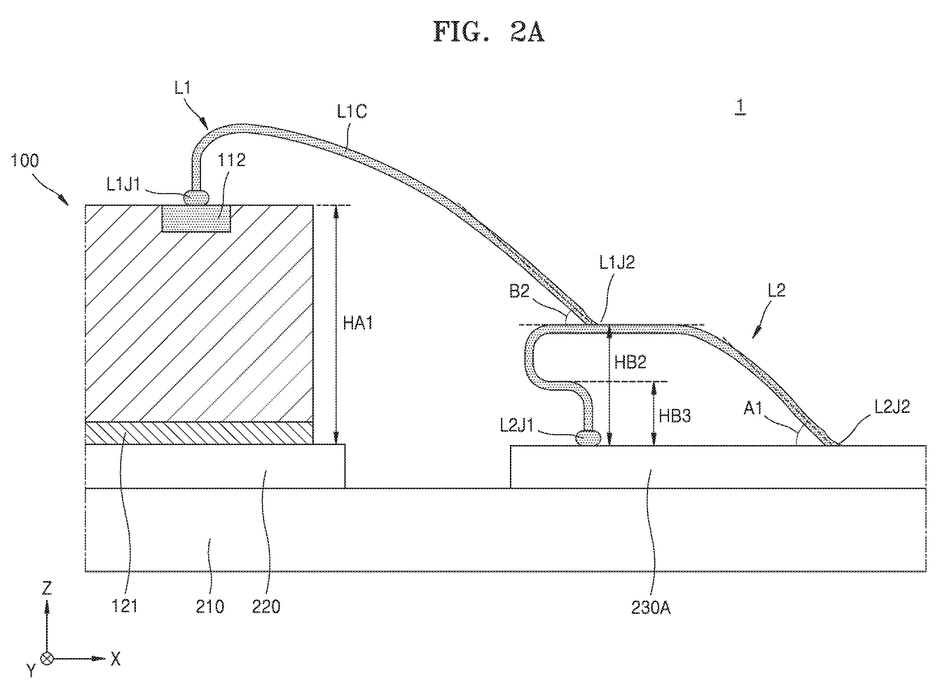

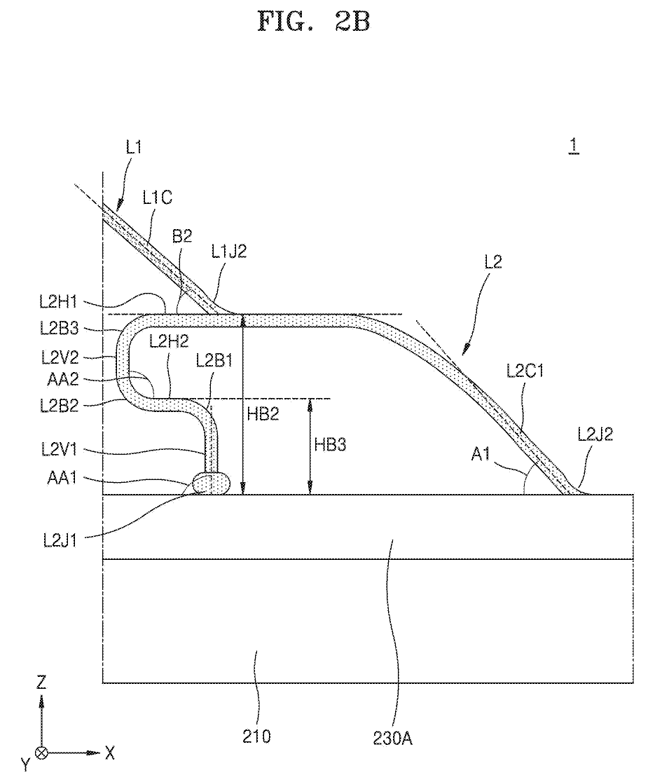

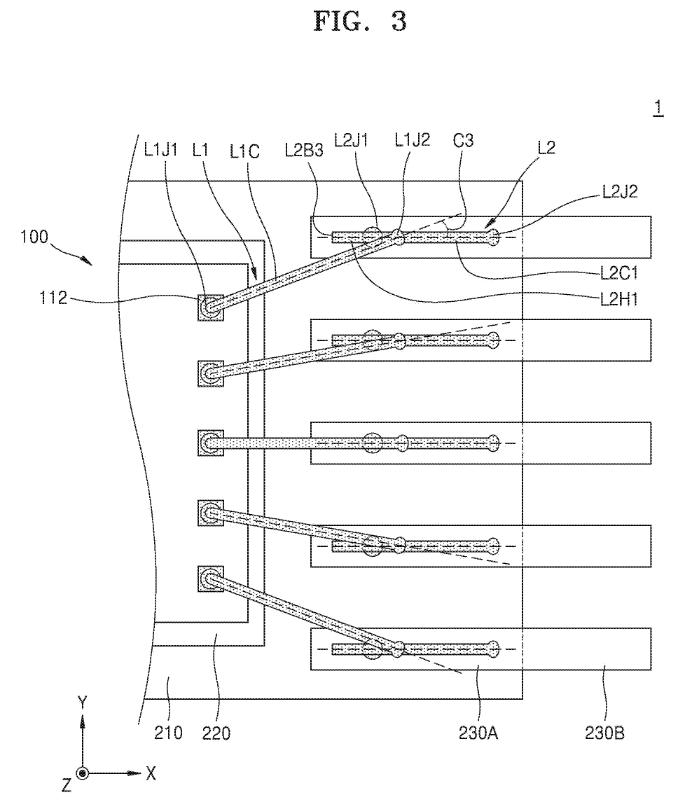

FIG. 1 is a side view of a semiconductor package 1 according to some implementations. FIG. 2A is an enlarged side view of a part of the semiconductor package 1 according to some implementations. FIG. 2B is an enlarged side view of a part of the semiconductor package 1 according to some implementations. More specifically, FIG. 2B is the enlarged side view of the part of the semiconductor package 1 with respect to a first loop conductive wire L2. FIG. 3 is a planar view of the semiconductor package 1 according to some implementations.

Referring to FIGS. 1, 2A, 2B, and 3, the semiconductor package 1 may include a substrate 210, a first plate 220 provided on the substrate 210, a conductive plate 230A spaced laterally apart from the first plate 220 and disposed on the substrate 210 in a planar view, a semiconductor device 100 disposed on the first plate 220, the first loop conductive wire L2 provided on the conductive plate 230A, and a second conductive wire L1 electrically connecting a chip pad 112 of the semiconductor device 100 to the first loop conductive wire L2.

The semiconductor device 100 may be provided on the first plate 220 disposed on the substrate 210, and an adhesive layer 121 may be disposed between the semiconductor device 100 and the first plate 220. The conductive plate 230A may be disposed on the substrate 210. The conductive plate 230A may be laterally spaced apart from the semiconductor device 100 in a planar view. A conductive plate extension 230B extending by protruding outward from the outer edge of the substrate 210 may extend from the conductive plate 230A.

The semiconductor package 1 according to implementations disclosed in the drawings of the specification may be a lead frame package platform. In some implementations, the semiconductor package may be in any suitable platform other than the lead frame package platform. In addition to the case where the first loop conductive wire L2 is disposed on the conductive plate 230A corresponding to a lead in the lead frame package, a case where the first loop conductive wire L2 is disposed on a connection pad provided on a printed circuit board (PCB) substrate or a connection pad provided on a redistribution structure may also be included in the semiconductor package 1 according to implementations.

The first plate 220 and the conductive plate 230A may be disposed on the substrate 210. For example, the first plate 220 and the conductive plate 230A may have the same vertical thickness at the same vertical level. The first plate 220 and the conductive plate 230A may have different thicknesses, and a vertical level of the first plate 220 may be higher than a vertical level of the conductive plate 230A, or the vertical level of the conductive plate 230A may be higher than the vertical level of the first plate 220.

In the specification, although the first plate 220 and the conductive plate 230A are disposed on the substrate 210, at least a part of each of the first plate 220 and the conductive plate 230A may be surrounded by the substrate 210, or only an upper surface of each of the first plate 220 and the conductive plate 230A may be exposed from the substrate 210 to the outside.

One or more semiconductor devices 100 may be disposed on the first plate 220. For example, unlike as shown in the specification, two or more semiconductor devices 100 may be disposed on the first plate 220. The second conductive wire L1 and the first loop conductive wire L2 which will be described below may be electrically connected to at least some of a plurality of chip pads 112 provided on two or more semiconductor devices 100. As shown in FIG. 1, the second conductive wire L1 may extend laterally with respect to the semiconductor device 100, but may extend in various directions as well as laterally opposite to the semiconductor device 100. In addition, as shown in FIG. 2, the conductive plate 230A may be provided on the opposite side of the semiconductor device 100, but is not limited thereto.

The semiconductor device 100 may include, for example, one or more logic chips and/or one or more memory chips. The logic chip may be a system on chip (SoC). The logic chip may be a microprocessor. For example, the logic chip may be an application processor (AP), a micro-processor, a central processing unit (CPU), a graphics processing unit (GPU), a neural processing unit (NPU), a controller, or an application specific integrated circuit (ASIC). The memory chip may include various types of memory circuits, such as dynamic random-access memory (DRAM), static random-access memory (SRAM), flash, phase-change random-access memory (PRAM), resistive random-access memory (ReRAM), ferroelectric random-access memory (FeRAM), or magnetic random-access memory (MRAM).

The semiconductor device 100 may include one or more semiconductor chips, and the semiconductor chip may include a semiconductor substrate. The semiconductor substrate may include, for example, silicon. Alternatively, the semiconductor substrate may include a semiconductor element such as germanium, or a compound semiconductor such as silicon carbide (SiC), gallium arsenide (GaAs), indium arsenide (InAs), and indium phosphide (InP). Alternatively, the semiconductor substrate may have a silicon on insulator (SOI) structure. For example, the semiconductor substrate may include a buried oxide layer (BOX). The semiconductor substrate may include a conductive region, for example, an impurity-doped well or an impurity-doped structure. In addition, the semiconductor substrate may have various device isolation structures such as a shallow trench isolation (STI) structure.

The plurality of chip pads 112 may be provided on an upper surface of the semiconductor device 100. The adhesive layer 121 may be disposed on a lower surface of the semiconductor device 100, which is a surface opposite to the upper surface of the semiconductor device 100. The second conductive wire L1 corresponding to the chip pad 112 may be connected to the chip pad 112. A third end L1J1 of the second conductive wire L1 may be connected to the chip pad 112.

The first loop conductive wire L2 may be provided on the conductive plate 230A. The first loop conductive wire L2 may include a first end L2J1, a first vertical extension L2V1 connected to the first end L2J1, a second horizontal extension L2H2, a second vertical extension L2V2, a first horizontal extension L2H1, a first inclined extension L2C1, and a second end L2J2.

Each of the first end L2J1 and the second end L2J2 may be in direct contact with the conductive plate 230A. The first end L2J1 may be one end of the first loop conductive wire L2, and the second end L2J2 may be the other end of the first loop conductive wire L2. The first end L2J1 may correspond to a wire ball. The second end L2J2 may correspond to a stitch. The first end L2J1 may be disposed closer to the semiconductor device 100 than the second end L2J2. Alternatively, the first end L2J1 may be disposed farther away from the outer edge of the substrate 210 than the second end L2J2. The first end L2J1 and the second end L2J2 may be provided on the same conductive plate 230A.

The wire ball may be formed by partially deforming a wire at a first bonded portion during a bonding process of the first loop conductive wire L2 which will be described below. A horizontal width of the wire ball may be greater than a thickness of the first loop conductive wire L2. For example, the wire ball may be 2 to 4 times the diameter of the first loop conductive wire L2. In a planar view, the shape of the wire ball may be circular or elliptical. The wire ball may be formed in a starting process of wire bonding. However, the inventive concept is not limited by the shape of the wire ball.

The stitch may have, for example, a contact surface that is approximately circular or elliptical in a planar view, or may be in the form of a diamond shape or an irregular ellipse. In some implementations, a wire tail due to the remaining wire may extend in the stitch, and may be adjusted in a range of, for example, 1 to 3 times the diameter of the wire. Alternatively, the wire tail may not be provided.

The stitch may have a shape formed by flatly deforming one end of the first loop conductive wire L2 due to heat, pressure, etc. For example, the stitch may be deformed to a thickness of about 10 % to about 60 % the diameter of the first loop conductive wire L2 to be in direct contact with the conductive plate 230A. The first inclined extension L2C1 may extend from the second end L2J2 including the stitch. The stitch may be formed in a bonding completing process in a wire bonding process. However, the stitch may vary depending on an output during bonding, bonding pressure, bonding temperature, bonding time, and the shape of a wire bonding apparatus in the wire bonding process, and thus the shape of the stitch is not limited.

The first vertical extension L2V1 may extend upward from the first end L2J1 including the wire ball. The second horizontal extension L2H2 may extend laterally from the first vertical extension L2V1. The second vertical extension L2V2 may extend upward from the second horizontal extension L2H2. The first horizontal extension L2H1 may extend laterally from the second vertical extension L2V2. The first inclined extension L2C1 may extend from the first horizontal extension L2H1 to be inclined downward where the conductive plate 230A is located. The first inclined extension L2C1 may be connected to the second end L2J2 including the stitch.

In other words, one end of the first vertical extension L2V1 may be connected to the first end L2J1, and the other end of the first vertical extension L2V1 may be connected to the second horizontal extension L2H2. One end of the second horizontal extension L2H2 may be connected to the first vertical extension L2V1, and the other end of the second horizontal extension L2H2 may be connected to the second vertical extension L2V2. One end of the first horizontal extension L2H1 may be connected to the second vertical extension L2V2, and the other end of the first horizontal extension L2H1 may be connected to the first inclined extension L2C1. One end of the first inclined extension L2C1 may be connected to the first horizontal extension L2H1, and the other end of the first inclined extension L2C1 may be connected to the second end L2J2.

The first end L2J1, the first vertical extension L2V1, the second horizontal extension L2H2, the second vertical extension L2V2, the first horizontal extension L2H1, the first inclined extension L2C1, and the second end L2J2 may continuously extend and be integrally provided.

The first loop conductive wire L2 may have a first bending portion L2B1 between the first vertical extension L2V1 and the second horizontal extension L2H2. A direction in which the first vertical extension L2V1 extends and a direction in which the second horizontal extension L2H2 extends may be different from each other.

In a component of the direction in which the first vertical extension L2V1 extends, a third direction component may be greater than a first direction (X direction) component and a second direction (Y direction) component. For example, the direction in which the first vertical extension L2V1 extends may be the third direction (Z direction). For example, a first angle AA1, which is an angle formed between the first vertical extension L2V1 and an upper surface of the conductive plate 230A, may be in a range of 80 ° to 100 °. That is, the first vertical extension L2V1 may extend in an approximately vertical direction with respect to the upper surface of the conductive plate 230A. Unless otherwise described in the specification, the description given above with respect to the first vertical extension L2V1 may be approximately equally applied to a vertical extension in the specification.

A component in the direction in which the second horizontal extension L2H2 extends may be a component of a horizontal direction (on an X-Y plane) including the first direction component and the second direction component. For example, the direction in which the second horizontal extension L2H2 extends may be the first direction. For example, an angle between the second horizontal extension L2H2 and the first vertical extension L2V1 in the first bending portion L2B1 may be in a range of 80 ° to 100 °.

In a planar view, the second horizontal extension L2H2 may protrude laterally from the first end L2J1. In other words, the second horizontal extension L2H2 may extend laterally from the first end L2J1 toward the semiconductor device 100. For example, the second horizontal extension L2H2 may extend in the first direction toward the semiconductor device 100.

Parts of the second horizontal extension L2H2, the second vertical extension L2V2 connected to the second horizontal extension L2H2, and the first horizontal extension L2H1 connected to the second vertical extension L2V2 may protrude toward the semiconductor device 100 with respect to the first end L2J1. Alternatively, parts of the second horizontal extension L2H2, the second vertical extension L2V2 connected to the second horizontal extension L2H2, and the first horizontal extension L2H1 connected to the second vertical extension L2V2 may also extend in a negative first direction (negative X-axis direction) with respect to the first end L2J1. In a planar view, for example, as shown in FIG. 3, a part of the first horizontal extension L2H1 may overlap the second horizontal extension L2H2 in a vertical direction, and a part of the first horizontal extension L2H1 may overlap the first end L2J1 in the vertical direction.

In some implementations, the direction in which the second horizontal extension L2H2 extends and the direction in which the first horizontal extension L2H1 extends may be slightly different from each other. In this case, in a planar view, the first horizontal extension L2H1 and the second horizontal extension L2H2 may not overlap in the vertical direction.

In the specification, an extension direction of a vertical extension as a part of the first loop conductive wire L2 is not limited to a complete vertical direction, and a horizontal extension also is not limited to a complete horizontal direction. For example, the horizontal extension may have an angle in a range of 80 ° to 100 ° with respect to a horizontal plane, and the vertical extension may have an angle in a range of -10 ° to +10 ° with respect to the horizontal plane. In other words, the vertical extension may have a large component in the third direction (Z direction), but may also include the first direction component and the second direction component. The horizontal extension may have a large component of the horizontal direction (direction in the X-Y plane) including the first direction and the second direction, but may also include the third direction component.

The first loop conductive wire L2 may have a second bending portion L2B2 between the second vertical extension L2V2 and the second horizontal extension L2H2. A direction in which the second vertical extension L2V2 extends and the direction in which the second horizontal extension L2H2 extends may be different from each other.

In a component of the direction in which the second vertical extension L2V2 extends, the third direction component may be greater than the first direction (X direction) component and the second direction (Y direction) component. For example, the direction in which the second vertical extension L2V2 extends may be the third direction (Z direction). For example, an angle formed between the second vertical extension L2V2 and a surface parallel to the upper surface of the conductive plate 230A may be in a range of 80 ° to 100 °. That is, the second vertical extension L2V2 may extend in an approximately vertical direction with respect to the surface parallel to the upper surface of the conductive plate 230A.

The first loop conductive wire L2 may have a third bending portion L2B3 between the second vertical extension L2V2 and the first horizontal extension L2H1. The direction in which the second vertical extension L2V2 extends and the direction in which the first horizontal extension L2H1 extends may be different from each other.

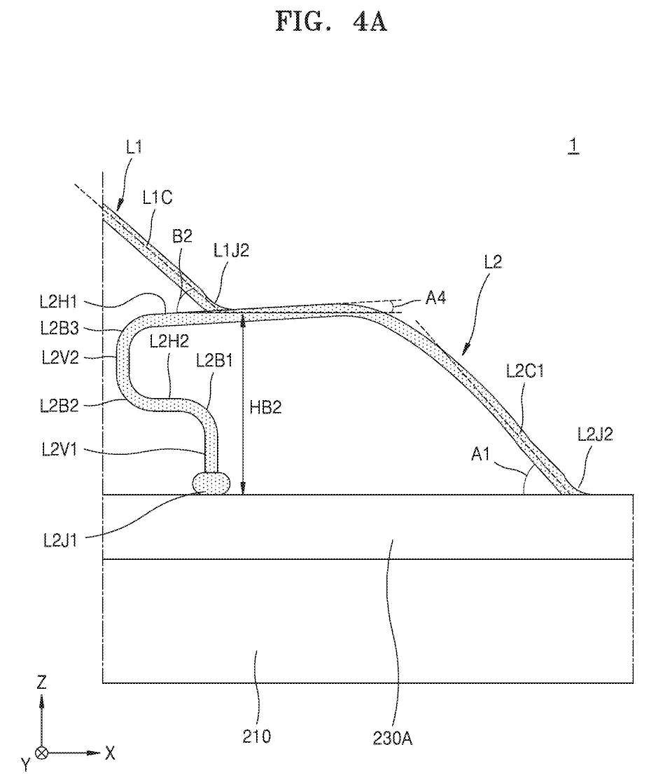

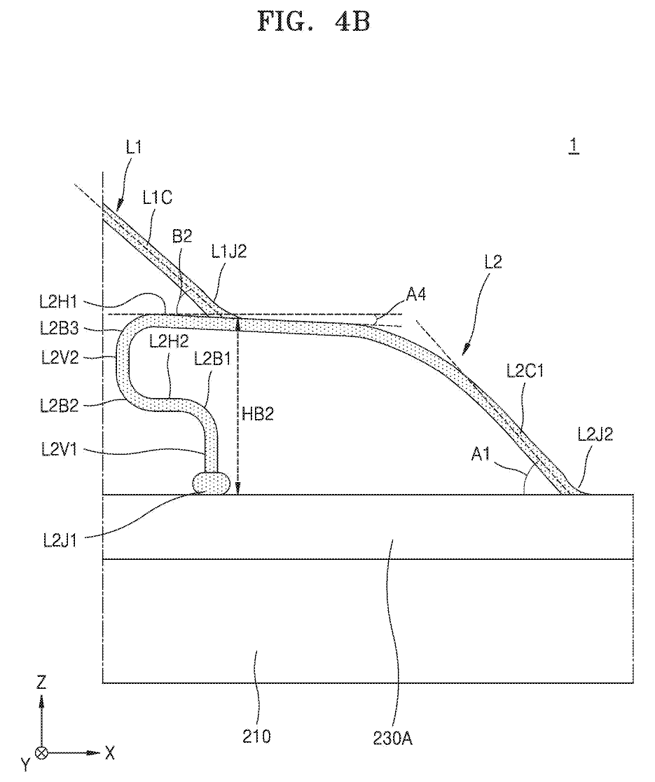

A component of the direction in which the first horizontal extension L2H1 extends may be the horizontal direction (on the X-Y plane) component including the first direction component and the second direction component. For example, the direction in which the first horizontal extension L2H1 extends may be the first direction. For example, the first horizontal extension L2H1 may be parallel to the surface parallel to the upper surface of the conductive plate 230A. However, as will be described below in FIGS. 4A and 4B, the first horizontal extension L2H1 is not limited to only being parallel to the surface parallel to the upper surface of the conductive plate 230A. This will be described with reference to FIGS. 4A and 4B.

In a planar view, a part of the first horizontal extension L2H1 may protrude laterally from the first end L2J1. In other words, a part of the first horizontal extension L2H1 may extend laterally from the first end L2J1 toward the semiconductor device 100. For example, a part of the first horizontal extension L2H1 may extend in the first direction toward the semiconductor device 100.

The first horizontal extension L2H1 may be directly connected to the second conductive wire L1. For example, a fourth end L1J2 of the second conductive wire L1 may be in direct contact with a side surface of the first horizontal extension L2H1. The fourth end L1J2 may similarly include a stitch similar to the above-described stitch of the second end L2J2. For example, the fourth end L1J2 of the second conductive wire L1 may be in direct contact with and electrically connected to an upper surface of the first horizontal extension L2H1.

In a planar view, a direction in which the second horizontal extension L2H2 extends from the first end L2J1 is approximately opposite to a direction from the first end L2J1 to the second end L2J2, and thus the length of the first horizontal extension L2H1 may be ensured to be longer. The length of the first horizontal extension L2H1 is sufficiently ensured, and thus a part of the first horizontal extension L2H1 to which the second conductive wire L1 is to be bonded may be more sufficiently ensured.

A vertical level of a part of the second conductive wire L1 contacting the fourth end L1J2 from the upper surface of the conductive plate 230A of the first horizontal extension L2H1 may be referred to as a second height HB2. A vertical level of the second horizontal extension L2H2 from the upper surface of the conductive plate 230A may be referred to as a third height HB3. A vertical level of the upper surface of the semiconductor device 100 from an upper surface of the first plate 220 may be referred to as a first height HA1.

In some implementations, when the upper surface of the conductive plate 230A and the upper surface of the first plate 220 have the same vertical level, a second height HA2 may be 10 % to 50 % of the first height HA1. When the second height HA2 is too low compared to the first height HA1, because the difference between the first height HA1 and the second height HB2 is greater than the distance between the semiconductor device 100 and the fourth end L1J2, the size of a second inclination angle B2, which will be described below, may increase. When the size of the second inclination angle B2 is greater than a predetermined size, an external force such as an elastic force of a wire is greater than a bonding force of the fourth end L1J2 to the first loop conductive wire L2, and thus, the fourth end L1J2 of the second conductive wire L1 may more likely detach from the first loop conductive wire L2.

In some implementations, the third height HB3 may be 30 % to 70 % of the second height HB2. For example, the third height HB3 may be approximately half of the second height HB2.

The semiconductor package 1 according to some implementations secures a vertical height of a predetermined level through the first loop conductive wire L2 and then electrically connects the chip pad 112 to the first loop conductive wire L2 with the second conductive wire L1, and thus the second inclination angle B2, which is an angle at a connection portion of the second conductive wire L1, may be relatively small compared to the case where there is no first loop conductive wire L2. Accordingly, reliability of bonding of the fourth end L1J2 of the second conductive wire L1 may be achieved.

Each of the first loop conductive wire L2 and the second conductive wire L1 may include a metal including copper (Cu), aluminum (Al), tungsten (W), nickel (Ni), molybdenum (Mo), gold (Au), silver (Ag), chromium (Cr), tin (Sn), and titanium (Ti), or an alloy thereof. For example, a surface of each of the first loop conductive wire L2 and the second conductive wire L1 may be plated with gold or may include gold.

For example, each of the first loop conductive wire L2 and the second conductive wire L1 includes gold, or the second conductive wire L1 is directly bonded to the first loop conductive wire L2 plated with gold, and thus a great bonding force may be secured compared to the case where the second conductive wire L1 is bonded to the conductive plate 230A mainly including copper. That is, the second conductive wire L1 is directly bonded to the first loop conductive wire L2, and thus reliability of the semiconductor package 1 may be improved.

The first inclined extension L2C1 may be connected to the first horizontal extension L2H1. The first horizontal extension L2H1 may have an approximately linear shape, and the first inclined extension L2C1 may have a shape extending from the first horizontal extension L2H1 toward the upper surface of the conductive plate 230A at a gradually increasing inclination. In addition, a length of each of the first horizontal extension L2H1 and the first inclined extension L2C1 may be relatively greater than a length of each of the first vertical extension L2V1, the second horizontal extension L2H2, and the second vertical extension L2V2. A change in an extension direction occurring between the first horizontal extension L2H1 and the first inclined extension L2C1 may have a gentler shape than a change in directions of the first bending portion L2B1, the second bending portion L2B2, and the third bending portion L2B3 described above.

The first inclined extension L2C1 may be connected to the second end L2J2. In the second end L2J2, a first inclination angle A1, which is an angle formed between the first inclined extension L2C1 and the upper surface of the conductive plate 230A, may be in a range of 10 ° to 40 °. By adjusting the size of the first inclination angle A1 to the corresponding range, the reliability of bonding of the second end L2J2 to the conductive plate 230A may be achieved.

The third end L1J1 may be connected to the chip pad 112 provided on one surface of the semiconductor device 100, and the fourth end L1J2 may be connected to the first loop conductive wire L2. For example, the fourth end L1J2 may be in direct contact with a part of the first loop conductive wire L2, and may be in direct contact with and connected to an upper surface of the first horizontal extension L1H1 of the first loop conductive wire L2.

The third end L1J1 may be one end of the second conductive wire L1, and the fourth end L1J2 may be the other end of the second conductive wire L1. The third end L1J1 may correspond to a wire ball. The fourth end L1J2 may correspond to a stitch. The wire ball may be formed by partially deforming a wire at a first bonded portion during a bonding process of the second conductive wire L1, which will be described below. The stitch may have a shape formed by flatly deforming one end of the second conductive wire L1 due to heat, pressure, etc.

A second wire extension L1C of the second conductive wire L1 extending from the third end L1J1 may have a shape extending upward from the semiconductor device 100 and having a gentle shape toward the corresponding first loop conductive wire L2. The second wire extension L1C may be connected to the fourth end L1J2, and the fourth end L1J2 may be in direct contact with the upper surface of the first horizontal extension L1H1 of the first loop conductive wire L2.

Alternatively, in some implementations, the second conductive wire L1 may include a portion extending from the chip pad 112 in the third direction, bent to an inner side of the semiconductor device 100, and protruding to the inner side thereof rather than the outer edge of the semiconductor device 100, and the second wire extension L1C extending from the portion protruding to the inner side thereof rather than the outer edge of the semiconductor device 100. For example, a shape formed by a part of each of the second horizontal extension L2H2, the second vertical extension L2V2, and the first horizontal extension L2H1 corresponding to the portion protruding from the semiconductor device 100 from the first end L2J1 of the first loop conductive wire L2 may be reflected in the shape of the second conductive wire L1 in the same manner.

An angle formed between the second wire extension L1C of the second conductive wire L1 and the first horizontal extension L2H1 of the first loop conductive wire L2 near the fourth end L1J2 may be referred to as the second inclination angle B2. The second inclination angle B2 may be in a range of 10 ° to 40 °. By adjusting the size of the second inclination angle B2 to the corresponding range, the reliability of bonding of the fourth end L1J2 to the first horizontal extension L2H1 may be achieved.

Due to the first loop conductive wire L2, a length of the second conductive wire L1 may be reduced compared to the case where there is no first loop conductive wire L2. In addition, due to the first loop conductive wire L2, an angle (e.g., the second inclination angle B2) formed between the extension direction of the second conductive wire L1 to an object to be bonded at an end (e.g., the fourth end L1J2) to which the second conductive wire L1 is bonded may be reduced compared to the case where there is no first loop conductive wire L2. Due to the first loop conductive wire L2, a vertical level difference between both bonded ends of the second conductive wire L1 may be reduced compared to the case where there is no first loop conductive wire L2.

The stress applied to the second conductive wire L1 may be reduced through structural characteristics in which the length of the second conductive wire L1 is relatively reduced, the second inclination angle B2 which is not excessively large at a bonding portion of the second conductive wire L1 is secured, and the vertical level difference between the third end L1J1 and the fourth end L1J2 is reduced. In the semiconductor package 1 according to some implementations, defects due to contact between other adjacent second conductive wires L1 shown in FIG. 4 which will be described below may be reduced, prevented, and avoided. In addition, in the semiconductor package 1, the reliability of bonding of the bonding portion (e.g., the fourth end L1J2) of the second conductive wire L1 may be achieved. Accordingly, the reliability of wire bonding of the semiconductor package 1 may be improved.

As shown in FIGS. 1-2B, a second inclination angle B2 between the second wire extension L1C of the second conductive wire L1 and the first horizontal extension L2H1 of the first loop conductive wire L2 may be observed in a side view. On the other hand, in a planar view of FIG. 3, a third inclination angle C3 between the second wire extension L1C of the second conductive wire L1 and the first horizontal extension L2H1 of the first loop conductive wire L2 may be observed. That is, with respect to the plane (X-Y plane), an angle between the second wire extension L1C of the second conductive wire L1 and the first horizontal extension L2H1 of the first loop conductive wire L2 may be referred to as a third inclination angle C3. The third inclination angle C3 may be formed because a pitch, which is a distance between the adjacent chip pads 112 among the plurality of chip pads 112 provided on the semiconductor device 100, is less than the distance between the adjacent conductive plates 230A among the plurality of conductive plates 230A provided in the semiconductor package 1.

In the semiconductor package 1, the second conductive wire L1 is directly bonded to a part of the first loop conductive wire L2 at the fourth end L1J2, and thus the reliability of bonding between the fourth end L1J2 and the first loop conductive wire L2 may be reduced when the third inclination angle C3 is greater than a predetermined size. Therefore, for example, the size of the third inclination angle C3 may be in a range of 0 ° to 30 °. Alternatively, the third inclination angle C3 may be in a range of -30 ° to 30 °. In a planar view as shown in FIG. 3, a clockwise direction may be referred to as a positive angle, and a counterclockwise direction may be referred to as a negative angle.

The plurality of conductive plates 230A of the semiconductor package 1 according to some implementations are all illustrated in shapes parallel to each other. However, unlike this, the plurality of conductive plates 230A may be disposed to radially spread with respect to the center (e.g., the semiconductor device 100) such that the distance between the adjacent conductive plates 230A increases away from the center. Alternatively, some of the plurality of conductive plates 230A may be disposed parallel to each other, and the remaining conductive plates 230A may be radially disposed.

When the plurality of conductive plates 230A are radially disposed, the size of the third inclination angle C3 may be small compared to the case where the plurality of conductive plates 230A are disposed parallel to each other.

FIG. 4A is an enlarged side view of a part of the semiconductor package 1 according to some implementations. FIG. 4B is an enlarged side view of a part of the semiconductor package 1 according to some implementations. More specifically, FIGS. 4A and 4B are enlarged side views of the part of the semiconductor package 1 with respect to the first loop conductive wire L2. Descriptions not given below may be substantially the same as or similar to the descriptions above.

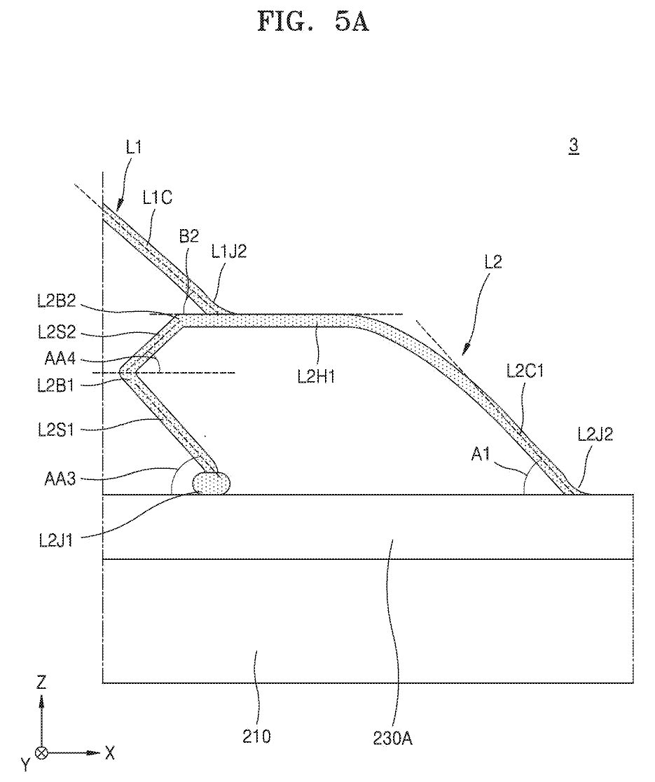

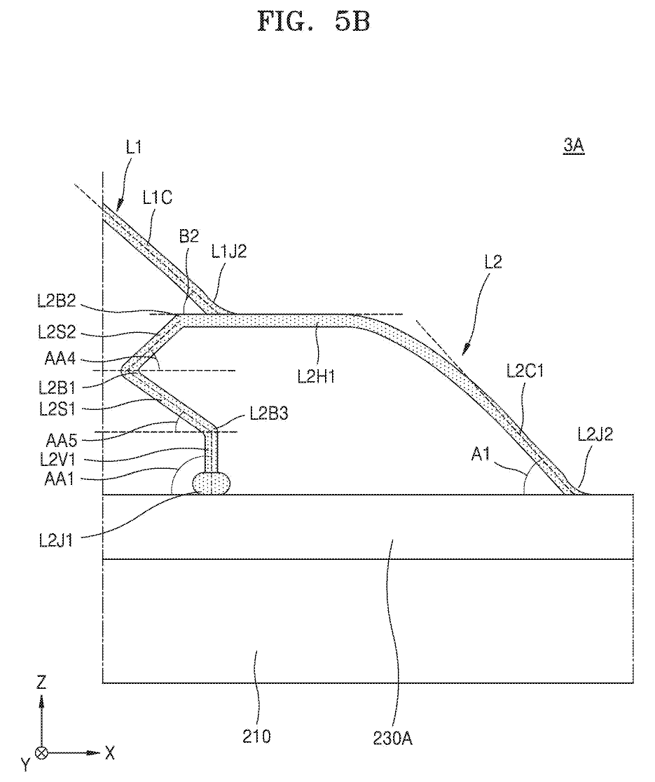

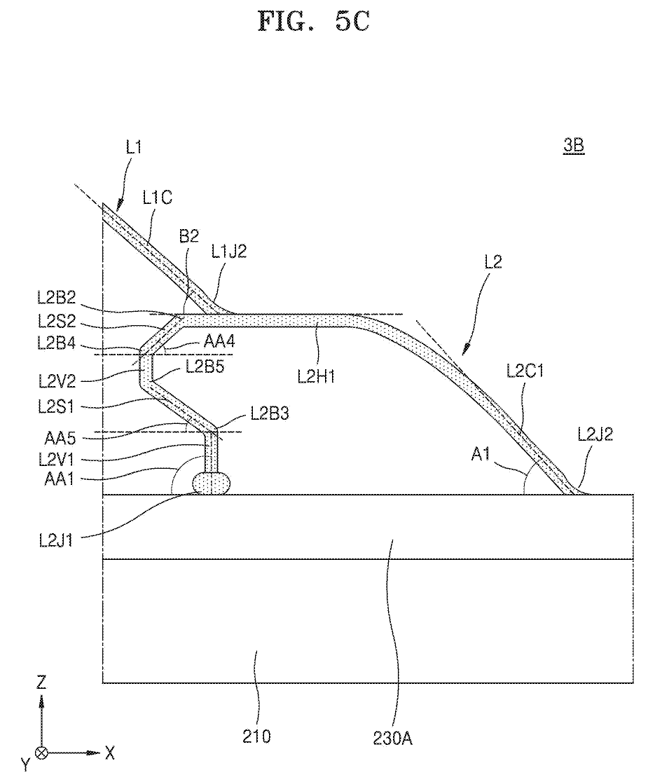

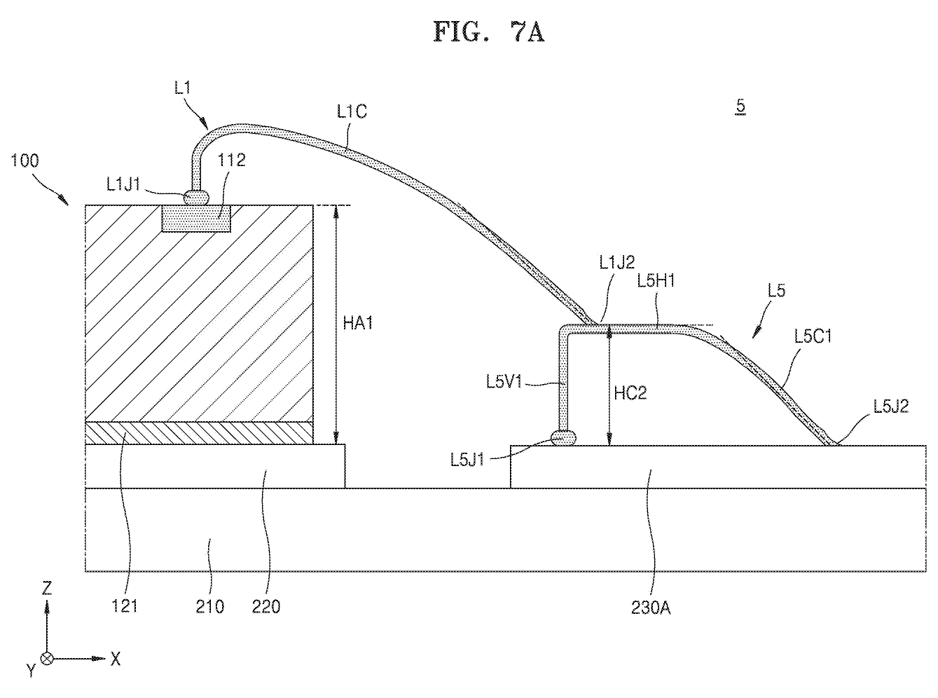

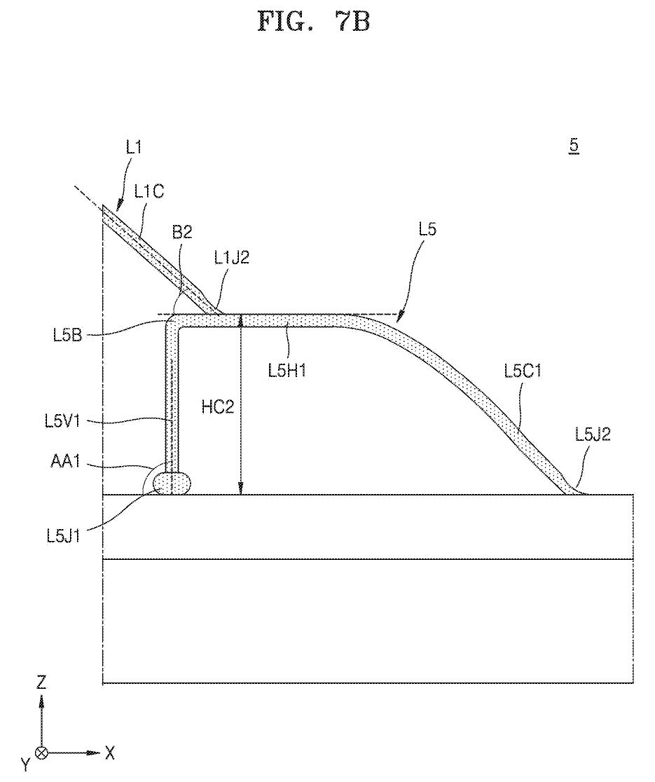

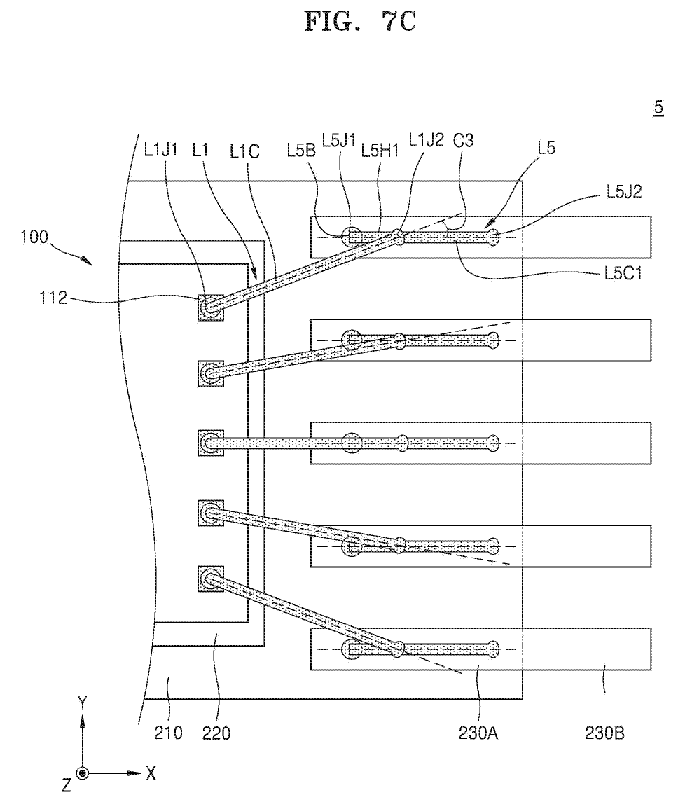

Referring to FIGS. 4A and 4B, a fourth inclination angle A4, which is an angle formed between the first horizontal extension L2H1 and a surface parallel to an upper surface of the conductive plate 230A, may be formed. The fourth inclination angle A4 may be in a range of -10 ° to +10 °. A positive angle may mean the fourth inclination angle A4 in a clockwise direction with respect to a horizontal dotted line indicating the surface parallel to the upper surface of the conductive plate 230A as shown in FIG. 4A, and a negative angle may mean the fourth inclination angle A4 in a counterclockwise direction with respect to the horizontal dashed line indicating the surface parallel to the upper surface of the conductive plate 230A as shown in FIG. 4B. Thereafter, in some implementations of FIGS. 5A-5C and 7A-7C which will be described below, each of the first horizontal extensions L2H1 and L5H1 may also have the fourth inclination angle A4 as shown in FIGS. 4A and 4B.

FIG. 5A is an enlarged side view of a part of a semiconductor package 3 according to some implementations. FIG. 5B is an enlarged side view of a part of the semiconductor package 3A according to some implementations. FIG. 5C is an enlarged side view of a part of the semiconductor package 3B according to some implementations. Descriptions not given below may be substantially the same as or similar to the descriptions above.

Referring to FIG. 5A, the semiconductor package 3 according to some implementations may include the first loop conductive wire L2. The first loop conductive wire L2 may include the first end L2J1, a first diagonal extension L2S1, a second diagonal extension L2S2, the first horizontal extension L2H1, the first inclined extension L2C1, and the second end L2J2, and the components may extend in the order listed above.

A third angle AA3, which is an angle formed between an extension line of the first diagonal extension L2S1 and an upper surface of the conductive plate 230A in the first end L2J1, may be in a range of, for example, 30 ° to 80 °. A direction component of the first diagonal extension L2S1 may have, for example, a first direction component and a third direction component from the first end L2J1. The first diagonal extension L2S1 may extend from the first end L2J1 in a direction in which the semiconductor device 100 is provided so as to face the semiconductor device 100 with respect to the first end L2J1. For example, the first diagonal extension L2S1 may extend in a first negative direction with respect to the first end L2J1.

The second diagonal extension L2S2 may extend from the first diagonal extension L2S1 to the first horizontal extension L2H1. In a planar view, the second diagonal extension L2S2 may protrude in a direction in which the semiconductor device 100 is disposed with respect to the first end L2J1. As described above, the first horizontal extension L2H1 may be in direct contact with the fourth end L1J2 of the second conductive wire L1.

The first loop conductive wire L2 may have the first bending portion L2B1 between the first diagonal extension L2S1 and the second diagonal extension L2S2. In addition, the first loop conductive wire L2 may have the second bending portion L2B2 between the second diagonal extension L2S2 and the first horizontal extension L2H1. A change in an extension direction occurring between the first horizontal extension L2H1 and the first inclined extension L2C1 may have a gentler shape than a change in directions of the first bending portion L2B1 and the second bending portion L2B2 described above.

Referring to FIG. 5B, the semiconductor package 3A according to some implementations may include the first loop conductive wire L2. The first loop conductive wire L2 may include the first end L2J1, the first vertical extension L2V1, the first diagonal extension L2S1, the second diagonal extension L2S2, the first horizontal extension L2H1, the first inclined extension L2C1, and the second end L2J2, and the components may extend in the order listed above.

In a component of the direction in which the first vertical extension L2V1 extends, a third direction component may be greater than a first direction (X direction) component and a second direction (Y direction) component. For example, the direction in which the first vertical extension L2V1 extends may be the third direction (Z direction). For example, the first angle AA1, which is an angle formed between the first vertical extension L2V1 and an upper surface of the conductive plate 230A, may be in a range of 80 ° to 100 °. That is, the first vertical extension L2V1 may extend in an approximately vertical direction with respect to the upper surface of the conductive plate 230A.

A fifth angle AA5, which is an angle formed between the first diagonal extension L2S1 with respect to a direction parallel to the upper surface of the conductive plate 230A, may be in a range of 30 ° to 80 °. A fourth angle AA4, which is an angle formed between the second diagonal extension L2S2 with respect to the direction parallel to the upper surface of the conductive plate 230A, may be in a range of 30 ° to 80 °.

The first loop conductive wire L2 may have the third bending portion L2B3 between the first vertical extension L2V1 and the first diagonal extension L2S1. The first loop conductive wire L2 may have the first bending portion L2B1 between the first diagonal extension L2S1 and the second diagonal extension L2S2. In addition, the first loop conductive wire L2 may have the second bending portion L2B2 between the second diagonal extension L2S2 and the first horizontal extension L2H1. A change in an extension direction occurring between the first horizontal extension L2H1 and the first inclined extension L2C1 may have a gentler shape than a change in directions of the first bending portion L2B1 and the second bending portion L2B2 described above.

Referring to FIG. 5C, the semiconductor package 3B according to some implementations may include the first loop conductive wire L2. The first loop conductive wire L2 may include the first end L2J1, the first vertical extension L2V1, the first diagonal extension L2S1, the second vertical extension L2V2, the second diagonal extension L2S2, the first horizontal extension L2H1, the first inclined extension L2C1, and the second end L2J2, and the components may extend in the order listed above.

The second vertical extension L2V2 may extend in an approximately vertical direction may be provided between the first diagonal extension L2S1 and the second diagonal extension L2S2. In a component of the direction in which the second vertical extension L2V2 extends, a third direction component may be greater than a first direction (X direction) component and a second direction (Y direction) component. The second vertical extension L2V2 may extend in an approximately vertical direction with respect to the upper surface of the conductive plate 230A.

The first loop conductive wire L2 may have a fifth bending portion L2B5 between the first diagonal extension L2S1 and the second vertical extension L2V2, and may also have the second bending portion L2B2 between the second vertical extension L2V2 and the second diagonal extension L2S2. An angle between directions in which the first diagonal extension L2S1 and the second vertical extension L2V2 extend with respect to the fifth bending portion L2B5 may be an obtuse angle, and an angle between directions in which the second vertical extension L2V2 and the second diagonal extension L2S2 extend with respect to the second bending portion L2B2 may be an obtuse angle.

The semiconductor package 3 of FIG. 5A, the semiconductor package 3A of FIG. 5B, and the semiconductor package 3B of FIG. 5C may respectively improve reliability of the semiconductor packages 3, 3A and 3B through the first loop conductive wire L2.

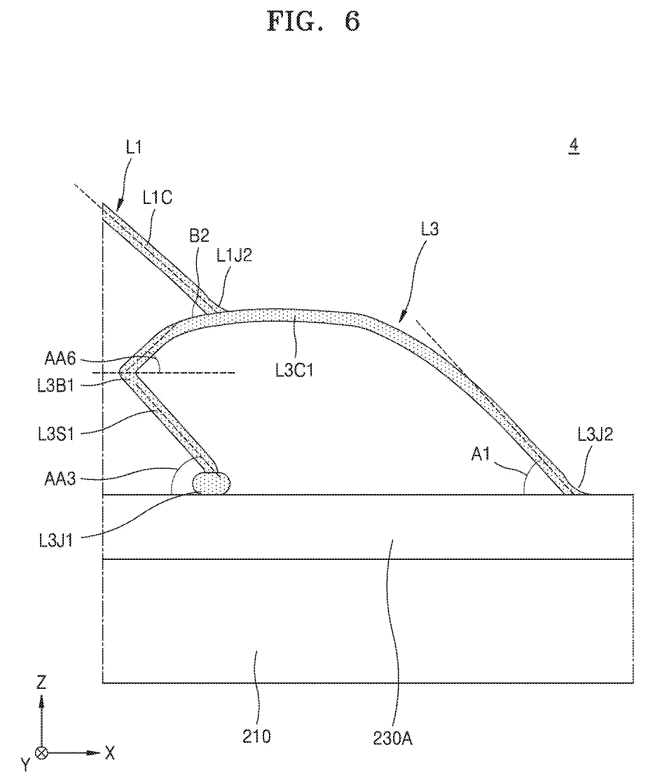

FIG. 6 is an enlarged side view of a part of a semiconductor package 4 according to some implementations. Descriptions not given below may be substantially the same as or similar to the descriptions above.

A first loop conductive wire L3 may include a first diagonal extension L3S1 extending from a first end L3J1, and a first curve extension L3C1 extending from the first diagonal extension L3S1 to a second end L3J2. The first loop conductive wire L3 may have a first bending portion L3B1 between the first diagonal extension L3S1 and the first curve extension L3C1. A sixth angle AA6, which is an angle formed between the first curve extension L3C1 extending from the first bending portion L3B1 and a surface parallel to an upper surface of the conductive plate 230A, may be in a range of 30 ° to 60 °.

In a process in which the first curve extension L3C1 is gradually bent and extends from the first bent portion L3B1 to the second end L3J2, the fourth end L1J2 of the second conductive wire L1 may be in direct contact with a part of the first curve extension L3C1, which is relatively far from the conductive plate 230A, to connect the first loop conductive wire L3 to the second conductive wire L1.

FIG. 7A is an enlarged side view of a part of a semiconductor package 5 according to some implementations. FIG. 7B is an enlarged side view of a part of the semiconductor package 5 according to some implementations. FIG. 7C is a planar view of the semiconductor package 5 according to some implementations. Descriptions not given below may be substantially the same as or similar to the descriptions above.

Referring to FIGS. 7A, 7B, and 7C, the semiconductor package 5 may include the substrate 210, the first plate 220 provided on the substrate 210, the conductive plate 230A spaced laterally apart from the first plate 220 and disposed on the substrate 210, the semiconductor device 100 disposed on the first plate 220, a first loop conductive wire L5 provided on the conductive plate 230A, and the second conductive wire L1 electrically connecting the chip pad 112 of the semiconductor device 100 to the first loop conductive wire L5.

The first loop conductive wire L5 may be provided on the conductive plate 230A. The first loop conductive wire L5 may include a first end L5J1, a first vertical extension L5V1 connected to the first end L5J1, the first horizontal extension L5H1, a first inclined extension L5C1, and a second end L5J2.

Each of the first end L5J1 and the second end L5J2 may be in direct contact with the conductive plate 230A. The first end L5J1 may be one end of the first loop conductive wire L5, and the second end L5J2 may be the other end of the first loop conductive wire L5. The first end L5J1 may correspond to a wire ball. The second end L5J2 may correspond to a stitch.

The first vertical extension L5V1 may extend upward from the first end L5J1 including the wire ball. The first horizontal extension L5H1 may extend laterally from the first vertical extension L5V1. The first inclined extension L5C1 may extend from the first horizontal extension L5H1 to be inclined downward. The first inclined extension L5C1 may be connected to a second end L5J2 including the stitch.

The first vertical extension L5V1 may extend in an approximately vertical direction with respect to an upper surface of the conductive plate 230A. For example, the first angle AA1, which is an angle formed between the first vertical extension L5V1 and the upper surface of the conductive plate 230A, may be in a range of 80 ° to 100 °.

The first loop conductive wire L5 may have a sixth bending portion L5B between the first vertical extension L5V1 and the first horizontal extension L5H1. An angle between a direction in which the first vertical extension L5V1 extends and a direction in which the first horizontal extension L5H1 extends with respect to the sixth bending portion L5B may be approximately vertical. For example, the angle between the direction in which the first vertical extension L5V1 extends and the direction in which the first horizontal extension L5H1 extends with respect to the sixth bending portion L5B may be in a range of 80 ° to 100 °.

An angle formed between the first horizontal extension L5H1 and a surface parallel to the upper surface of the conductive plate 230A may be in a range of -10 ° to +10 °. An angle between the first inclined extension L5C1 and the upper surface of the conductive plate 230A may be in a range of 10 ° to 40 °. An angle formed between the second wire extension L1C of the second conductive wire L1 and the first horizontal extension L5H1 of the first loop conductive wire L2 near the fourth end L1J2 may be referred to as the second inclination angle B2. The second inclination angle B2 may be in a range of 10 ° to 40 °.

In a planar view as shown in FIG. 7C, at least a part of the first end L5J1 and at least a part of the sixth bending portion L5B may overlap in a vertical direction. In the planar view as shown in FIG. 7C, the first horizontal extension L5H1 and the first inclined extension L5C1 extending from the sixth bending portion L5B may have shapes extending between the first end L5J1 and the second end L5J2.

In the planar view as shown in FIG. 7C, a third inclination angle C3 between the second wire extension L1C of the second conductive wire L1 and the first horizontal extension L5H1 of the first loop conductive wire L5 may be observed. For example, the size of the third inclination angle C3 may be in a range of 0 ° to 30 °. Alternatively, the third inclination angle C3 may be in a range of -30 ° to 30 °. In the planar view as shown in FIG. 7C, a clockwise direction may be referred to as a positive angle, and a counterclockwise direction may be referred to as a negative angle.

A vertical level of a part of the second conductive wire L1 contacting the fourth end L1J2 from the upper surface of the conductive plate 230A of the first horizontal extension L5H1 may be referred to as a second height HC2. A vertical level of the upper surface of the semiconductor device 100 from an upper surface of the first plate 220 may be referred to as the first height HA1.

In some implementations, when the upper surface of the conductive plate 230A and the upper surface of the first plate 220 have the same vertical level, the second height HC2 may be 10 % to 50 % of the first height HA1. When the second height HC2 is too low compared to the first height HA1, because the difference between the first height HA1 and the second height HC2 is greater than the distance between the semiconductor device 100 and the fourth end L1J2, the size of the second inclination angle B2, which will be described below, may increase. When the size of the second inclination angle B2 is greater than a predetermined size, an external force such as an elastic force of a wire is greater than a bonding force of the fourth end L1J2 to the first loop conductive wire L2, and thus, the fourth end L1J2 of the second conductive wire L1 may more likely detach from the first loop conductive wire L2.

The semiconductor package 5 according to some implementations secures a vertical height of a predetermined level through the first loop conductive wire L2 and then electrically connects the chip pad 112 to the first loop conductive wire L2 with the second conductive wire L1, and thus the second inclination angle B2, which is an angle at a connection portion of the second conductive wire L1, may be relatively small compared to the case where there is no first loop conductive wire L2. Accordingly, reliability of bonding of the fourth end L1J2 of the second conductive wire L1 may be achieved.

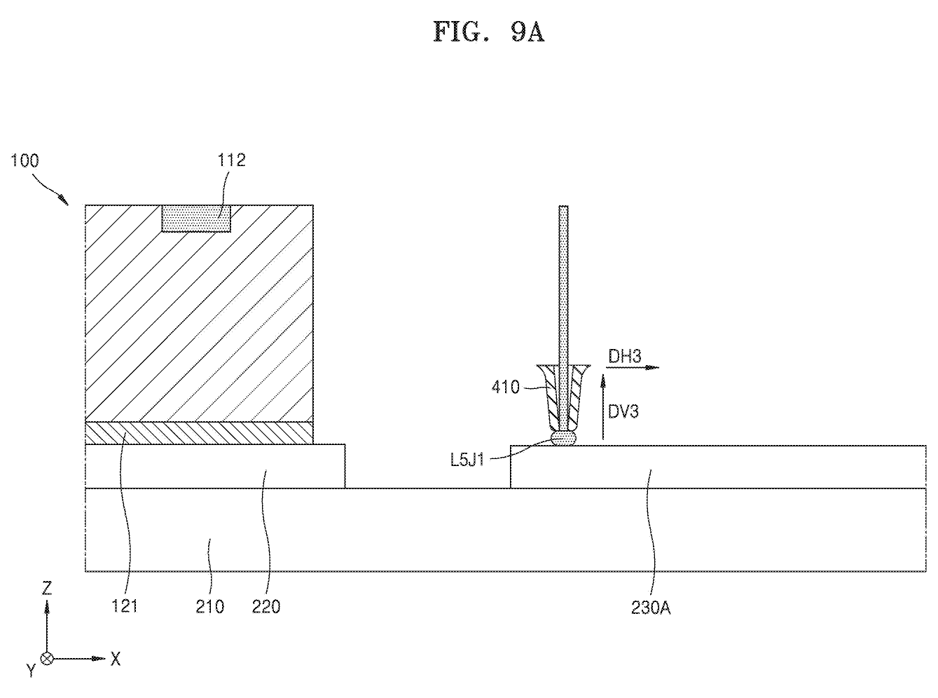

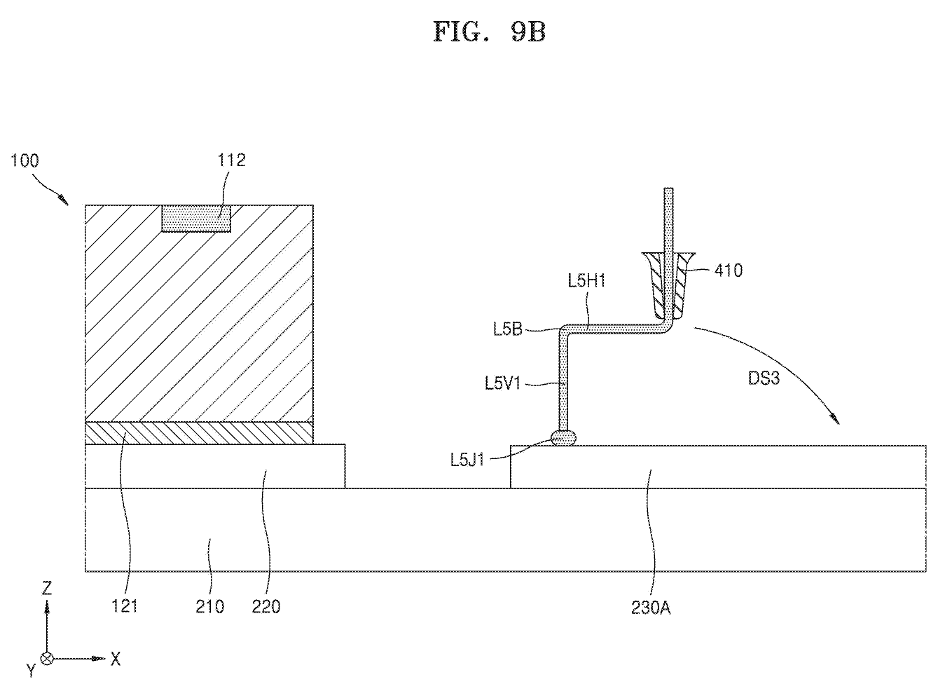

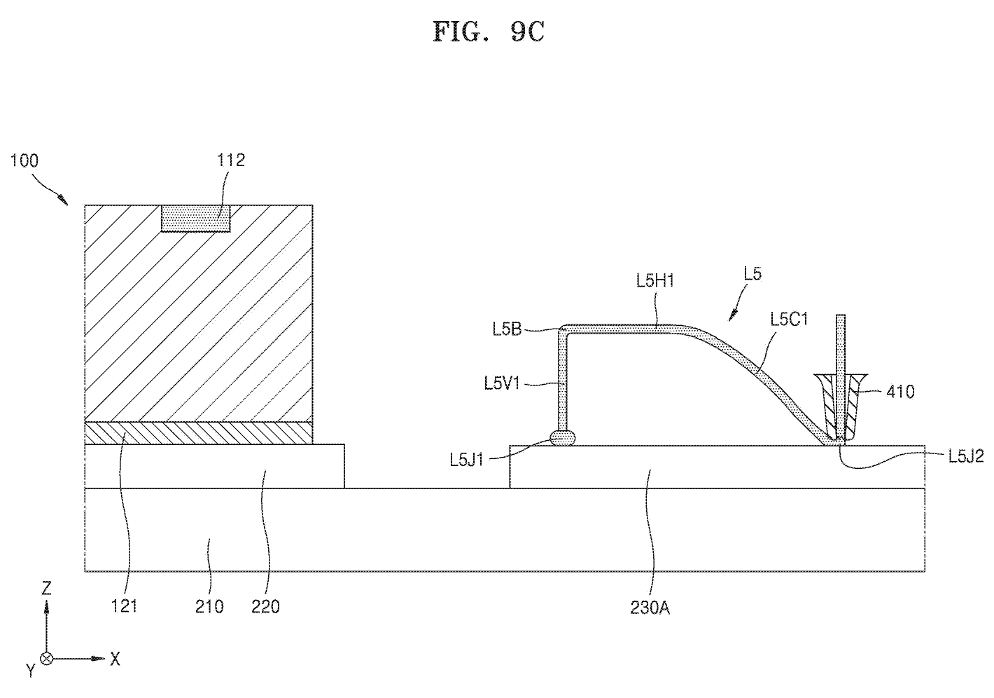

In the semiconductor package 5 according to some implementations, the stress applied to the second conductive wire L1 may be reduced through structural characteristics in which the length of the second conductive wire L1 is relatively reduced, the second inclination angle B2 which is not excessively large at a bonding portion of the second conductive wire L1 is secured, and the vertical level difference between the third end L1J1 and the fourth end L1J2 is reduced. The stress applied to the second conductive wire L1 is reduced, and thus defects due to contact between other adjacent second conductive wires L1 may be reduced, prevented, and avoided. In addition, in the semiconductor package 5, the reliability of bonding of the bonding portion (e.g., the fourth end L1J2) of the second conductive wire L1 may be achieved. Accordingly, the reliability of the semiconductor package 5 may be improved. In addition, the second conductive wire L1 is directly bonded to the first loop conductive wire L5, and thus the reliability of the semiconductor package 1 may be improved. In addition, the second loop conductive wire L5 is formed through the relatively simple process of FIGS. 9A-9C which will be described below, and thus the manufacturability of the semiconductor package 5 may be improved.

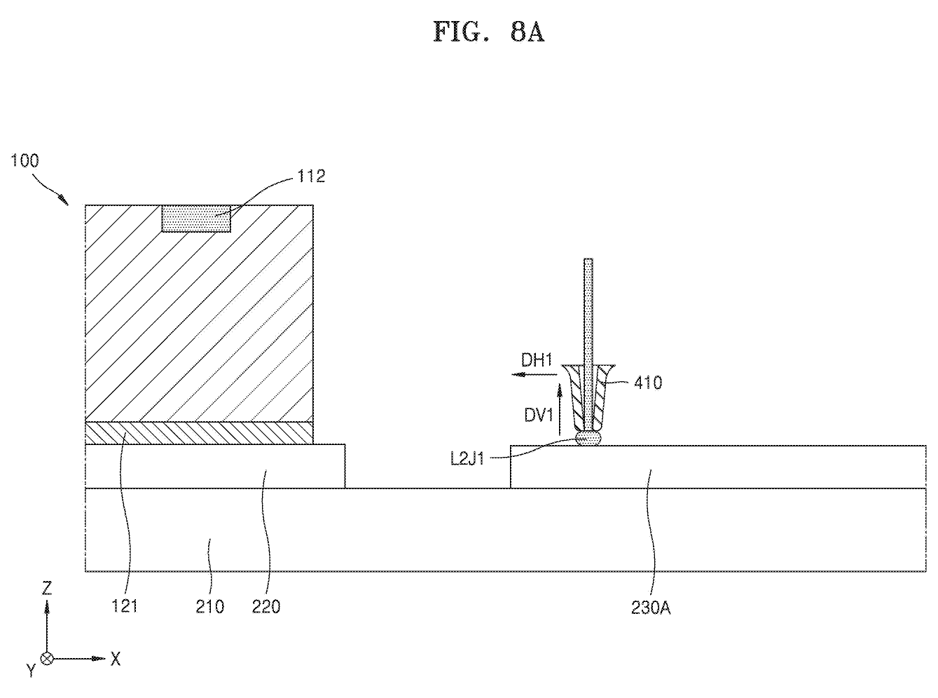

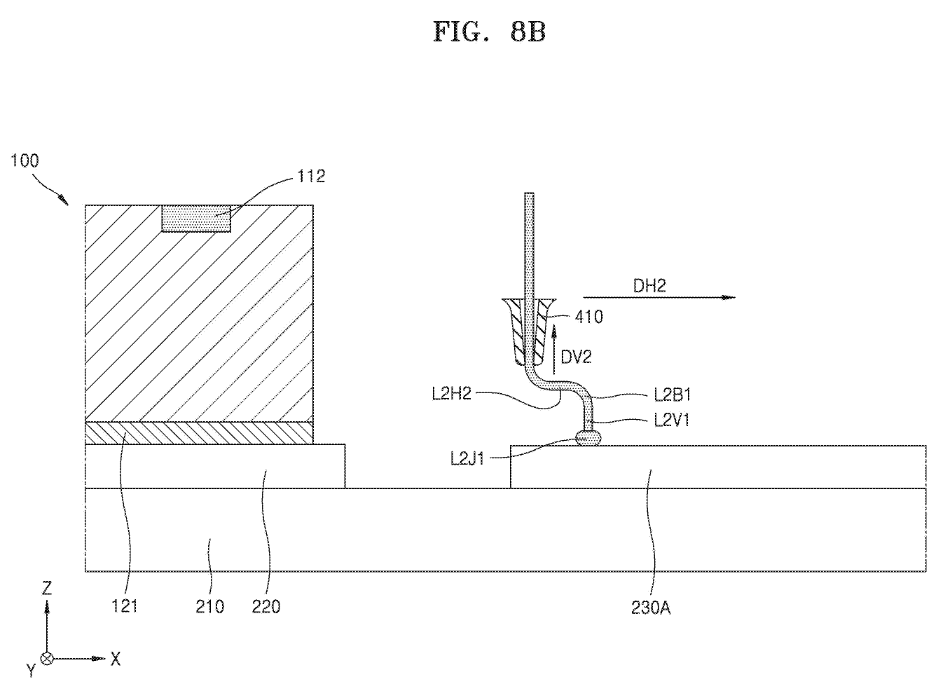

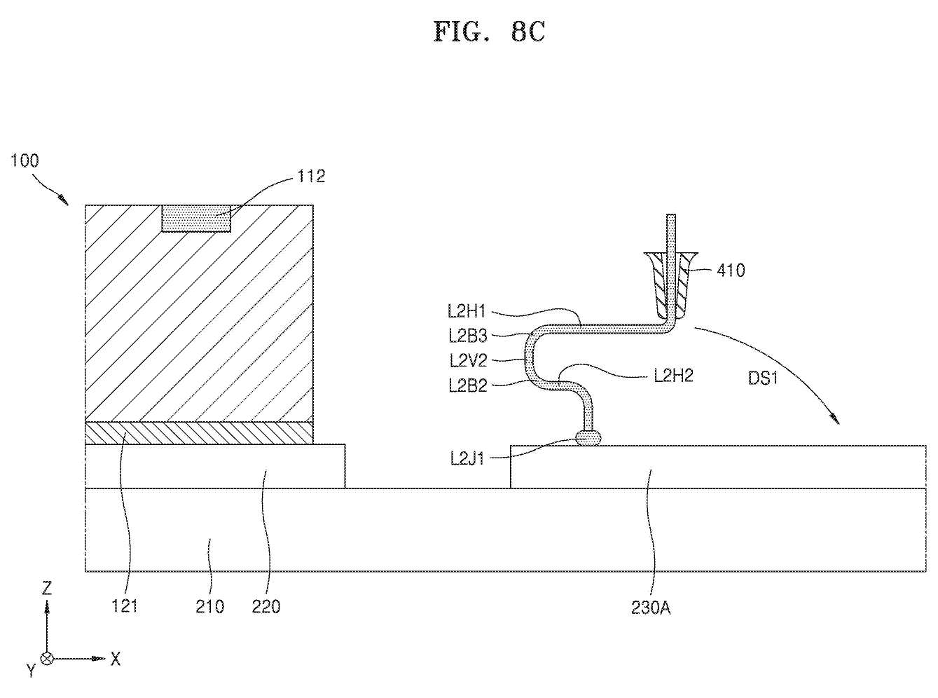

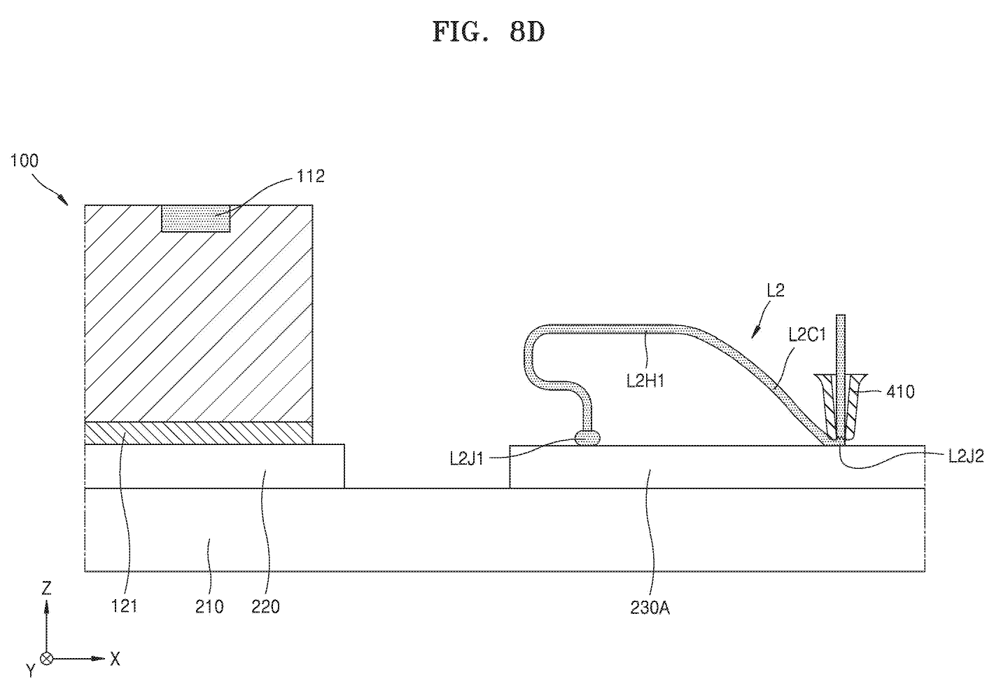

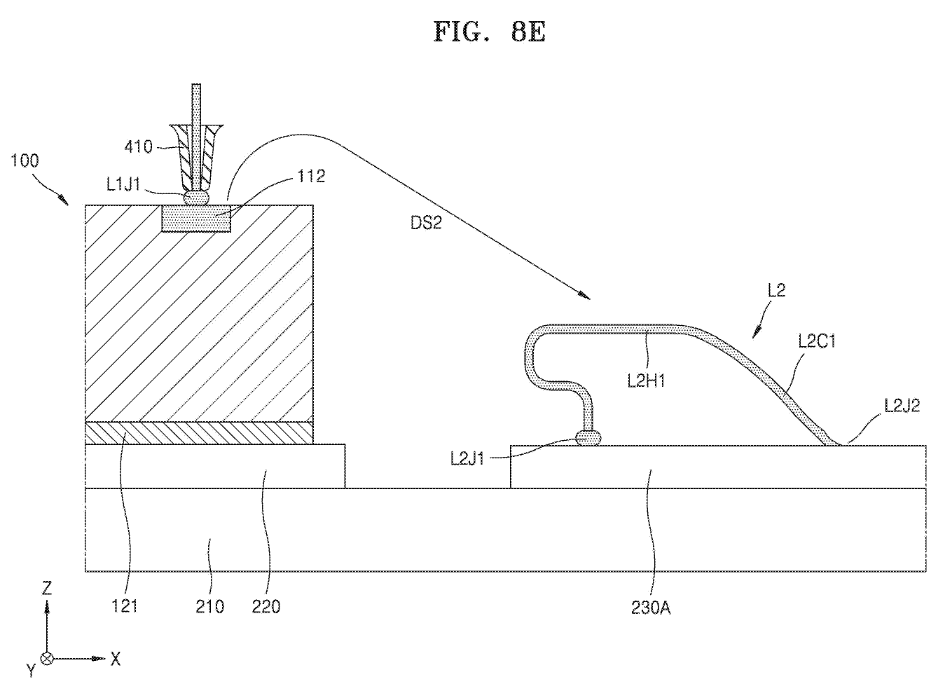

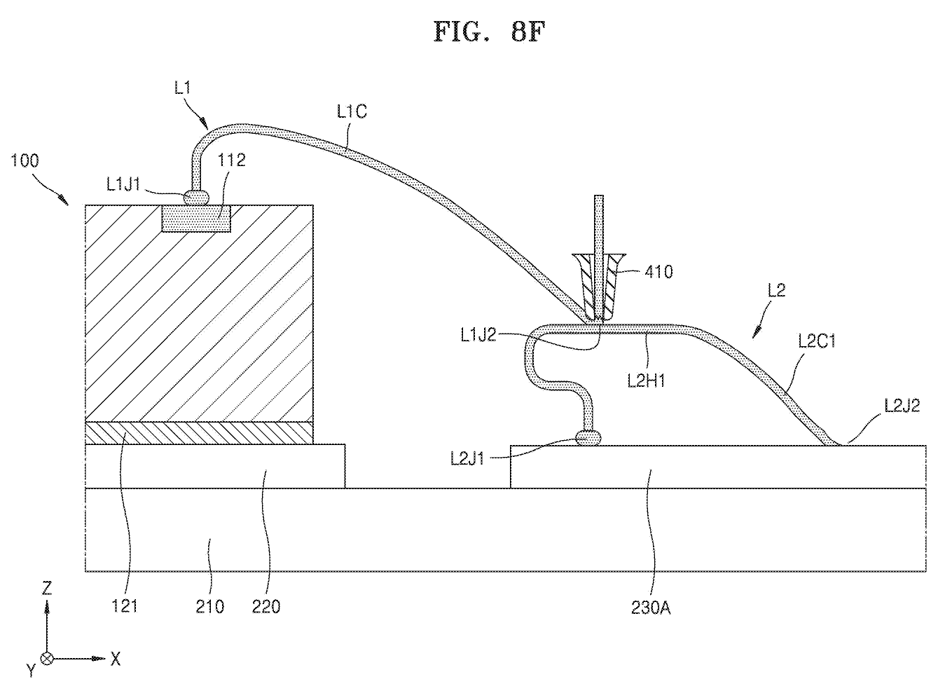

FIGS. 8A-8F are side views sequentially illustrating a method of manufacturing the semiconductor package 1 according to some implementations. Descriptions not given below may be substantially the same as or similar to the descriptions above.

Referring to FIG. 8A, a wire discharged from a capillary 410 may be bonded to an upper surface of the conductive plate 230A to form the first end L2J1 when energy such as pressure, ultrasonic vibration, and heat applied from the capillary 410 is applied to the wire. As shown in FIG. 8A, the capillary 410 may perform a first vertical motion DV1 and a first horizontal motion DH1. The wire may be continuously discharged from the capillary 410 while the capillary 410 performs the first vertical motion DV1 and the first horizontal motion DH1.

Referring to FIG. 8B, the first vertical extension L2V1, the first bending portion L2B1, and the second horizontal extension L2H2 may be formed through the first vertical motion DV1 and the first horizontal motion DH1. Thereafter, the capillary 410 may perform a second vertical motion DV2 and a second horizontal motion DH2.

Referring to FIG. 8C, the second bending portion L2B2, the second vertical extension L2V2, the third bending portion L2B3, and the first horizontal extension L2H1 may be formed through the second vertical motion DV2 and the second horizontal motion DH2. Thereafter, the capillary 410 may perform a first curve motion DS1.

Referring to FIG. 8D, the first inclined extension L2C1 may be formed through the first curve motion DS1 of the capillary 410. Thereafter, the wire discharged from the capillary 410 may be bonded to the upper surface of the conductive plate 230A to form the second end L2J2. After the second end L2J2 is formed on the conductive plate 230A, the capillary 410 may cut the wire to form the first loop conductive wire L2.

Referring to FIG. 8E, the wire discharged from the capillary 410 on the chip pad 112 may be bonded to the chip pad 112 to form the third end L1J1. Thereafter, the capillary 410 may continuously discharge the wire and perform the second curved motion DS2 from the third end L1J1 to reach the first horizontal extension L2H1 of the first loop conductive wire L2.

Referring to FIG. 8F, the second wire extension L1C may be formed through the second curve motion DS2 of the capillary 410. Thereafter, the wire discharged from the capillary 410 may be bonded to an upper surface of the first horizontal extension L2H1 of the first loop conductive wire L2 to form the fourth end L1J2. After the fourth end L1J2 is formed so that the second conductive wire L1 is bonded to the first loop conductive wire L2, the capillary 410 may cut the wire. Through the above-described process, the semiconductor package 1 according to some implementations may be manufactured.

FIGS. 9A-9C are side views sequentially illustrating a method of manufacturing the semiconductor package 5 according to some implementations. Descriptions not given below may be substantially the same as or similar to the descriptions above.

Referring to FIG. 9A, a wire discharged from the capillary 410 may be bonded to an upper surface of the conductive plate 230A to form the first end L5J1 when energy such as pressure, ultrasonic vibration, and heat applied from the capillary 410 is applied to the wire. As shown in FIG. 9A, the capillary 410 may perform a third vertical motion DV3 and a third horizontal motion DH3. The wire may be continuously discharged from the capillary 410 while the capillary 410 performs the third vertical motion DV3 and the third horizontal motion DH3.

Referring to FIG. 9B, the first vertical extension L5V1, the sixth bending portion L5B, and the first horizontal extension L5H1 may be formed through the third vertical motion DV3 and the third horizontal motion DH3 of the capillary 410. Thereafter, the capillary 410 may perform a third curve motion DS3 on the upper surface of the conductive plate 230A from the first horizontal extension L5H1 in a direction away from the first end L5J1.

Referring to FIG. 9C, the first inclined extension L5C1 may be formed through the third curve motion DS3 of the capillary 410. Thereafter, the wire discharged from the capillary 410 may be bonded to the upper surface of the conductive plate 230A to form the second end L5J2. After the second end L5J2 is formed on the conductive plate 230A, the capillary 410 may cut the wire to form the first loop conductive wire L5. The subsequent process of manufacturing the semiconductor package 5 may be performed in substantially the same process as in FIGS. 8E and 8F of the semiconductor package 1 described above. Through the above-described process, the semiconductor package 5 according to some implementations may be manufactured.

In some aspects, the present disclosure provides a method of manufacturing a semiconductor package including forming a first end of a first loop conductive wire on a conductive plate, extending the first loop conductive wire, forming a second end of the first loop conductive wire on the conductive plate, forming a third end of the second conductive wire on a chip pad of a semiconductor device, extending the second conductive wire, and directly connecting a fourth end of the second conductive wire to the first loop conductive wire.

In addition, according to some implementations, the extending of the first loop conductive wire may include forming a first vertical extension of the first loop conductive wire, forming a first horizontal extension of the first loop conductive wire, and forming a first inclined extension of the first loop conductive wire, and the first vertical extension is connected to the first end and the first inclined extension is connected to the second end.

In addition, according to some implementations, a wire ball may be provided at the third end of the second conductive wire, a stitch may be provided at the fourth end of the second conductive wire, a wire ball may be provided at the first end of the first loop conductive wire, and a stitch may be provided at the second end of the first loop conductive wire.

In addition, according to some implementations, the extending of the first loop conductive wire may include forming a first horizontal extension of the first loop conductive wire, and the fourth end is in direct contact with and connected to the first horizontal extension.

In addition, according to some implementations, the extending of the first loop conductive wire may include forming a first horizontal extension of the first loop conductive wire, and the fourth end of the second conductive wire may be directly connected to the first horizontal extension, a second inclination angle formed between a part of the second conductive wire extending from the fourth end and the first horizontal extension may be in a range of 10 ° to 40 °, and a third inclination angle formed between the first horizontal extension of the first loop conductive wire and the second conductive wire may be in a range of 0 ° to 30 °.

In addition, according to some implementations, the first end of the first loop conductive wire may be formed before the second end, and the third end of the second conductive wire may be formed before the fourth end.

In addition, according to some implementations, the semiconductor device and the conductive plate may be provided on a substrate, and the conductive plate may extend outward from the outer edge of the substrate.

In addition, according to some implementations, a part of the first loop conductive wire may be formed to protrude from a position of the first end in a direction in which the semiconductor device is disposed so as to be closer to the semiconductor device than the first end.

In addition, according to some implementations, the extending of the first loop conductive wire may include forming a first vertical extension of the first loop conductive wire, forming a second horizontal extension of the first loop conductive wire, forming a second vertical extension of the first loop conductive wire, forming a first horizontal extension of the first loop conductive wire, and forming a first inclined extension of the first loop conductive wire, and the first end, the first vertical extension, the second horizontal extension, the second vertical extension, the first horizontal extension, the first inclined extension, and the second end may sequentially extend.

In addition, according to some implementations, a fourth inclination angle formed by the first horizontal extension with respect to a direction parallel to an upper surface of the conductive plate may be in a range of -10 ° to +10 °.

While the aspects of the present disclosure have been particularly shown and described with reference to implementations thereof, it will be understood that various changes in form and details may be made therein without departing from the spirit and scope of the following claims.

What is claimed is:

1. A semiconductor package comprising:
a semiconductor device comprising a chip pad on an upper surface of the semiconductor device;
a conductive plate laterally spaced apart from the semiconductor device in a plan view;
a first loop conductive wire on the conductive plate; and
a second conductive wire connecting the chip pad to the first loop conductive wire,
wherein each of a first end of the first loop conductive wire and a second end of the first loop conductive wire is connected to the conductive plate.

2. The semiconductor package of claim 1, wherein
the first end of the first loop conductive wire comprises a wire ball, the second end of the first loop conductive wire is free of a wire ball, and
the first end of the first loop conductive wire and the second end of the first loop conductive wire are laterally spaced apart from each other and are in contact with the conductive plate.

3. The semiconductor package of claim 2, wherein the second end of the first loop conductive wire is farther from the semiconductor device than the first end of the first loop conductive wire.

4. The semiconductor package of claim 2, wherein
the wire ball has a circular shape or an elliptical shape, and a lateral dimension of the wire ball is greater than a diameter of the first loop conductive wire, and
the second end comprises a stitch.

5. The semiconductor package of claim 1, comprising an adhesive layer, wherein
the semiconductor device is on the adhesive layer,
one end of the second conductive wire is connected to the first loop conductive wire, and
a vertical distance between the one end of the second conductive wire and the conductive plate is in a range of 10 % to 50 % of a vertical distance between the upper surface of the semiconductor device and a lower surface of the adhesive layer.

6. The semiconductor package of claim 1, wherein
the first loop conductive wire comprises a first vertical extension and a first inclined extension,
the first vertical extension is connected to the first end of the first loop conductive wire,
the first inclined extension is connected to the second end of the first loop conductive wire, and
a first angle defined between the first vertical extension and a plane of the conductive plate is in a range of 80 ° to 100 °.

7. The semiconductor package of claim 6, wherein a first inclination angle defined between the first inclined extension and the conductive plate is in a range of 10 ° to 40 °.

8. The semiconductor package of claim 1, wherein
the second conductive wire comprises a third end and a fourth end, and
the third end is connected to the chip pad, and the fourth end is directly connected to the first loop conductive wire.

9. The semiconductor package of claim 8, wherein
a wire ball is at the third end of the second conductive wire, and
a stitch is at the fourth end of the second conductive wire.

10. The semiconductor package of claim 8, wherein
the first loop conductive wire comprises a first horizontal extension,
a fourth inclination angle defined by the first horizontal extension relative to a direction parallel to an upper surface of the conductive plate is in a range of -10 ° to +10 °, and
the fourth end of the second conductive wire is in direct contact with the first horizontal extension.

11. The semiconductor package of claim 10, wherein
a second inclination angle defined between a part of the second conductive wire extending from the fourth end and an upper surface of the first horizontal extension is in a range of 10 ° to 40 °, and
a size of a third inclination angle, in a plan view and defined between the first horizontal extension of the first loop conductive wire and the second conductive wire is in a range of 0 ° to 30 °.

12. The semiconductor package of claim 1, wherein
the first loop conductive wire comprises a first vertical extension, a first horizontal extension, a second vertical extension, a second horizontal extension, and a first inclined extension,
the first vertical extension is connected to the first end of the first loop conductive wire and the first inclined extension is connected to the second end of the first loop conductive wire, and
the first vertical extension is connected to the second horizontal extension, the second horizontal extension is connected to the second vertical extension, and the second vertical extension is connected to the first horizontal extension.

13. The semiconductor package of claim 1, wherein
the second conductive wire comprises a third end and a fourth end, the fourth end of the second conductive wire being connected to the first loop conductive wire, and
a vertical distance between the fourth end of the second conductive wire and the conductive plate is in a range of 10 % to 50 % of a vertical distance between the upper surface of the semiconductor device and a reference level corresponding a level of the conductive plate.

14. The semiconductor package of claim 1, comprising a substrate, wherein
the semiconductor device and the conductive plate are on the substrate, and
the conductive plate extends outward from an outer edge of the substrate.

15. A semiconductor package comprising:
a semiconductor device comprising a chip pad on an upper surface of the semiconductor device;
a conductive plate laterally spaced apart from the semiconductor device in a plan view;
a first loop conductive wire on the conductive plate; and
a second conductive wire connecting the chip pad to the first loop conductive wire,
wherein each of a first end of the first loop conductive wire and a second end of the first loop conductive wire is connected to the conductive plate,
wherein the second conductive wire comprises a third end and a fourth end, the third end being connected to the chip pad, and the fourth end being directly connected to the first loop conductive wire, and
a portion of the first loop conductive wire protrudes from the first end of the first loop conductive wire toward the semiconductor device.

16. The semiconductor package of claim 15, wherein
the first loop conductive wire comprises a first vertical extension, a first horizontal extension, and a first inclined extension,
the first vertical extension is connected to the first end of the first loop conductive wire, the first inclined extension is connected to the second end of the first loop conductive wire, the first horizontal extension is connected to the first inclined extension, and
the fourth end of the second conductive wire is directly connected to the first horizontal extension.

17. The semiconductor package of claim 15, wherein
the first loop conductive wire comprises a first vertical extension, a first horizontal extension, a second vertical extension, a second horizontal extension, and a first inclined extension,
the first vertical extension is connected to the first end of the first loop conductive wire, and the first inclined extension is connected to the second end of the first loop conductive wire,
the first vertical extension is connected to the second horizontal extension, the second horizontal extension is connected to the second vertical extension, the second vertical extension is connected to the first horizontal extension, and the first horizontal extension is connected to the first inclined extension, and
the second horizontal extension protrudes and extends, in a direction away from the second end of the first loop conductive wire, from a portion of the second horizontal extension that is connected to the first vertical extension.

18. The semiconductor package of claim 15, wherein
the first loop conductive wire comprises a first vertical extension, a first horizontal extension, and a first inclined extension,
a first angle defined between the first vertical extension and a plane of the conductive plate is in a range of 80 ° to 100 °,
a first inclination angle defined between the first inclined extension and the conductive plate is in a range of 10 ° to 40 °, and
a third inclination angle defined between the first horizontal extension and the second conductive wire is in a range of 0 ° to 30 °.

19. The semiconductor package of claim 15, wherein
a first wire ball is at the third end of the second conductive wire,
a stitch is at the fourth end of the second conductive wire,
a second wire ball is at the first end of the first loop conductive wire, and
a stitch is at the second end of the first loop conductive wire.

20. A semiconductor package comprising:
a semiconductor device comprising a plurality of chip pads on a surface of the semiconductor device;
a plurality of conductive plates spaced apart from the semiconductor device;
a plurality of first loop conductive wires on at least some of the plurality of conductive plates; and
a plurality of second conductive wires connecting at least some of the plurality of chip pads to the plurality of first loop conductive wires,
wherein a first end and a second end of each of the plurality of first loop conductive wires are connected to respective conductive plate of the plurality of conductive plates,
wherein the first end of each first loop conductive wire is a wire ball, and the second end of each conductive wire is a stitch,
wherein a third end of each of the plurality of second conductive wires is connected to each of the plurality of chip pads,
wherein a fourth end of each of the plurality of second conductive wires is directly connected to each of the corresponding plurality of first loop conductive wires,
wherein the third end of each second conductive wire is a wire ball, and the fourth end of each second conductive wire is a stitch,
wherein the first end of each first loop conductive wire is on the conductive plate and closer to the semiconductor device than the second end of each first loop conductive wire,
wherein each of the plurality of first loop conductive wires comprises a first vertical extension, a first horizontal extension, and a first inclined extension,
wherein the first vertical extension is connected to the first end of the first loop conductive wire, the first inclined extension is connected to the second end of the first loop conductive wire, and the first horizontal extension is connected to the first inclined extension,
wherein a first angle defined between the first vertical extension and a plane of each of the plurality of conductive plates is in a range of 80 ° to 100 °,
wherein a first inclination angle defined between the first inclined extension and each of the plurality of conductive plates is in a range of 10 ° to 40 °, and
wherein a second inclination angle defined between the first horizontal extension and each of the plurality of second conductive wires is in a range of 0 ° to 30 °.
